(19) United States
(12) Patent Application Publication
(10) Pub. No.: US 2002/0195268 A1
(43) Pub. Date: Dec. 26, 2002

(54) THICK FILM CIRCUIT CONNECTION

(76) Inventor: Robert E. Schendel, Kingwood, TX (US)

Correspondence Address: Clarence E. Eriksen, 112 E. PECAN STREET, SUITE 2100, SAN ANTONIO, TX, 78205, US

(21) Appl. No.: 09/886,853

(22) Filed: Jun. 21, 2001

(51) Int. Cl. H05K 1/03

(52) U.S. Cl. 174/256

(57) ABSTRACT

A thick film circuit connection epoxy is provided for protecting connections of dissimilar metals in a thick film substrate from the effects of oxidation. In the fabrication of hybrid integrated circuits, aluminum leads on the integrated circuit die are connected to gold conductors on the thick film substrate by means of an ultrasonic weld. The present invention comprises disposing a silver-filled thermoplastic epoxy around the weld between the aluminum wire and the gold conductor. Physical and electrical integrity of the connection between the aluminum wire and the gold conductor is thus maintained, even if the weld fails due to oxidation at elevated operating temperatures.

### BACKGROUND OF THE INVENTION

1. Field of the Invention

The present invention relates to the fabrication of hybrid integrated circuits, and, more particularly, to the connection of an aluminum wire to a gold conductor of a thick film substrate utilizing a conductive silver-filled epoxy bond.

2. Description of the Prior Art

Hybrid integrated circuits are fabricated by interconnecting a plurality of integrated circuit die and other electrical components in a desired configuration on a substrate. Currently, thick film and thin film substrates are utilized in the fabrication of such hybrid circuits. When using thick film substrate, the interconnection of the die and other components involves connecting the aluminum leads on the die to gold conductors on the substrate. Such combinations are typically made using well-known ultrasonic welding techniques.

During operation of a hybrid integrated circuit having aluminum leads ultrasonically welded to gold conductors of a thick film substrate, it has been observed that oxides start to form at the aluminum/gold connection when the circuit temperature reaches approximately 165 degrees Celsius. Once the circuit temperature reaches approximately 200 degrees Celsius, additional oxides have formed at the connections such that there exists increased contact resistance within the circuit or there is a complete mechanical and electrical failure of the connection.

Thin film substrates have been used by the semiconductor industry to avoid the above-described problem. Thin film substrates utilize a monometallic bond to avoid the disadvantageous results that can occur at high temperatures using thick film substrates. However, the thin film substrates are substantially more expensive than the thick film substrates. Therefore, the semiconductor industry would find advantageous an improved bond which maintains electrical and mechanical integrity of the connections between dissimilar metals on a thick film substrate. This result has been achieved with the present invention.

### SUMMARY OF THE INVENTION

Method and apparatus for maintaining the electrical and mechanical integrity of electrical connections between dissimilar metals on a thick film substrate at high temperatures are disclosed. Such electrical connections are made by ultrasonically welding a wire made of a first metal, e.g. aluminum, to a conductor made of a second metal, e.g. gold.

In accordance with the present invention a silver-filled thermoplastic epoxy is disposed around the electrical connection between the dissimilar metals. At high temperatures, the silver-filled thermoplastic epoxy maintains the electrical and mechanical integrity of the electrical connection, even though the ultrasonic weld may fail as a result of oxidation at such temperatures.

### BRIEF DESCRIPTION OF THE DRAWINGS

In the accompanying drawings:

FIG. 1 is a top view of a portion of a thick film substrate containing an integrated circuit die.

FIG. 2 is a profile view of the components of the preferred embodiment of the present invention.

### DESCRIPTION OF THE PREFERRED EMBODIMENT

The following illustrative description of the present invention is provided to facilitate an understanding of the invention, and is not intended to limit the present invention to any specific form.

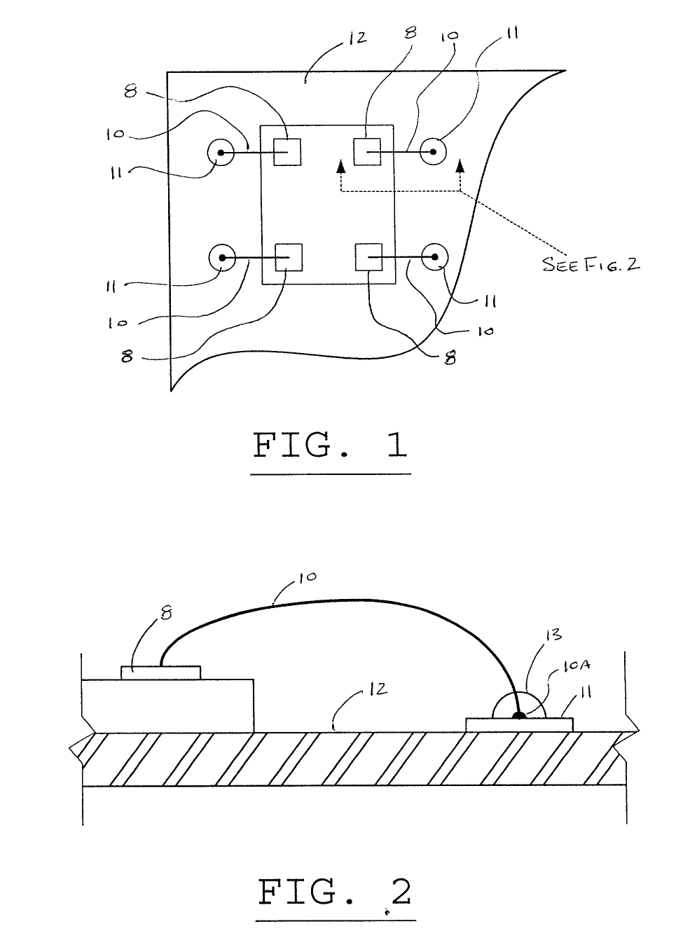

With reference to both FIGS. 1 and 2, the fabrication of hybrid integrated circuits on a thick film substrate comprises making electrical connections between leads 10 of an integrated circuit die of one metal, e.g. aluminum, and conductors 11 on the substrate made of another metal, e.g. gold. In FIGS. 1 and 2, an embodiment of the present invention comprises an aluminum lead 10 connected to a gold conductor 11 on a thick film substrate 12 by an ultrasonic weld connection 10A. Silver-filled thermoplastic epoxy 13 is then disposed completely around the ultrasonic weld connection 10A. Silver-filled thermoplastic epoxy is used in a preferred embodiment of the present invention, because silver is electrically compatible with both aluminum and gold. It is intended that any two dissimilar metals which are each compatible with silver particles suspended in the epoxy may be used.

During operation of a hybrid integrated circuit as illustrated in FIGS. 1 and 2, the temperature of the circuit may increase from room temperature to a level above 200 degrees Celsius. As the temperature approaches 165 degrees Celsius, the weld connection10A of the aluminum wire 10 and the gold conductor 11 may begin to oxidize. Once the temperature reaches 200 degrees Celsius, additional oxides may form in the weld connection 10A. Without benefit of the silver-filled thermoplastic epoxy 13, the oxidation might cause an increase in electrical resistance or a failure of the mechanical and electrical integrity of the connection. However, since the silver-filled thermoplastic epoxy 13 is bonded to both the aluminum wire 10 and the gold conductor 11, the physical integrity of the connection is maintained. Additionally, since the silver-filled thermoplastic epoxy 13 is highly conductive and is compatible with both aluminum and gold, the electrical integrity of the connection between the aluminum lead and the gold conductor is maintained, even though the weld connection may fail due to oxidation.

What is claimed is:

1. In a hybrid integrated circuit on a thick film substrate where the leads of the integrated circuit die are made from a first metal and are connected to conductors on the substrate which are made from a second metal, the improvement comprising a thermoplastic epoxy containing conductive metallic particles which is disposed around each welded connection between a lead and a conductor.

2. The hybrid integrated circuit of claim 1, wherein the first metal is aluminum, the second metal is a gold, and the aluminum lead and the gold conductor are welded by ultrasonic welding.

3. The hybrid integrated circuit of claim 1, wherein the epoxy is a silver-filled thermoplastic epoxy.

4. A hybrid integrated circuit comprising:
(a) a thick film substrate having gold conductors thereon;
(b) an integrated circuit die having aluminum leads which are ultrasonically welded to gold conductors on the substrate; and
(c) silver-filled thermoplastic epoxy which is disposed on and which covers each connection between a lead and a conductor.

5. A method of connecting a lead of an integrated circuit die to a conductor on a thick film substrate, comprising:
ultrasonically welding the lead of the integrated circuit die to the conductor; and
disposing a thermoplastic epoxy comprising conductive metallic particles around the weld between the lead of the integrated circuit die and the conductor.

6. The method of claim 5, wherein the lead of the integrated circuit die is made of aluminum and the conductor on the thick film substrate is made of gold.

7. The method of claim 5, wherein the epoxy is a silver-filled thermoplastic epoxy.
